(19) United States
(12) Patent Application Publication
(10) Pub. No.: US 2004/0191538 A1
(43) Pub. Date: Sep. 30, 2004

(54) Nanometer-controlled polymeric thin films that resist adsorption of biological molecules and cells

(76) Inventor: Xueying Huang, Hockessin, DE (US)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/785,150

(22) Filed: Feb. 24, 2004

Related U.S. Application Data
(60) Provisional application No. 60/451,068, filed on Feb. 28, 2003.

(51) Int. Cl. G03F 7/00

(52) U.S. Cl. 428/447; 428/500

(57) ABSTRACT

This invention relates to a process for growing thin films of polyethylene glycol alkyl acrylate (PEGAA) on a moiety accepting surface of a substrate using Surface Atom Transfer Radical Polymerization (SATRP). This invention also relates to a process for producing thin PEGAA films having specific surface functionalities, a thickness ranging from about 0.5 nm to about 5000 nm, and a PEGAA chain density ranging from 0.1 to 100% surface coverage. This invention further relates to articles coated with such films, wherein the coated articles resist adhesion of biological molecules and cells, as well as, to uses for the coated articles.

### FIELD OF THE INVENTION

This invention relates to a process for growing thin films of polyethylene glycol alkyl acrylate (PEGAA) on a moiety accepting surface of a substrate using Surface Atom Transfer Radical Polymerization (SATRP). This invention also relates to a process for producing thin PEGAA films having specific surface functionalities, a thickness ranging from about 0.5 nm to about 5000 nm, and a PEGAA chain density ranging from 0.1 to 100% surface coverage. This invention further relates to articles coated with such films, wherein the coated articles resist adhesion of biological molecules and cells, as well as, to uses for the coated articles.

### TECHNICAL BACKGROUND

Generally, bacterial adhesion to a surface occurs through two mechanisms: (i) biospecific/selective interactions, e.g, carbohydrate-protein or protein-protein interactions, and (ii) non-specific interactions, e.g. hydrophobic or electrostatic interactions. (Chapman et al., Langmuir, 1225, 1226, Vol. 17, No. 4 (2001). Bacteria and cells commonly adhere to the surface of a host by adhering to the proteins and/or polysaccharides that are adsorbed onto the host's surface. These proteins and/or polysaccharides are either already present in the host or are secreted by pathogens. Once the bacteria or cells adhere to a host's surface via proteins and/or polysaccharides, the bacteria begin to grow. As a result, bacteria and cells are generally not able to adhere to a host's surface unless a protein layer has first been adsorbed thereto. Accordingly, if the surface of the host is able to resist adsorption of proteins, an appreciable degree of bacterial, cellular and/or pathogenic adhesion to the host's surface will be prevented.

A surface's resistance to protein adsorption generally implies that the surface will be resistant to bacterial and cell adhesion. The process wherein bacteria and cells adhere to, and grow on a host's surface is known as “bio-fouling.” Surfaces that are able to resist bio-fouling are generally known as “inert” surfaces. For biocompatibility reasons, an inert surface is advantageous in many applications. For example, inert surfaces enable the incidence of (1) thrombosis caused by plasma-proteins that are adsorbed onto the surface of implanted devices, such as intravenous catheters, vascular implants, heart-valve implants, and other soft tissue implants and (2) the irritation that is caused by adsorbed proteins and/or adhered bacteria on external medical devices, such as contact lenses, to either be completely eliminated, or at least appreciably decreased. Inert surfaces can also help prevent the harmful build-up of bacteria on food packaging materials and the “hard fouling”, or build-up of barnacles and gorgonians on the hulls of ships. (Chapman et al.)

Polyethylene glycol (PEG) is at least one material that has been widely used to prevent proteins from adhering to the surface of biomedical devices. Typically, PEG is either utilized as a polymeric comonomer, is grafted onto the surface of the materials employed in manufacturing the device, or is incorporated into a coating that is applied to the surface of the device itself. The resistance of PEG-coated surfaces can be increased as the density and chain length of the grafted PEG films are increased. PEG, however, tends to auto-oxidize, especially when exposed to O₂ and transition metals, which are present in most biochemically relevant solutions. A PEG coated substrate, therefore, can eventually allow cells to attach to the substrate's surface in some applications. (Ostuni et al., Langmuir, 5605, 5606, Vol. 17, No. 18 (2001)).

Polyethylene oxide (PEO) is another material that has successfully been employed in preventing the adsorption of proteins. PEO prevents protein adsorption by being coated, grafted or adsorbed onto the surface of a substrate. (M. Zhang et al., Biomaterials, 1998, 19, 953-960.) The thickness required for PEO coatings/layers, however, limits its usefulness in applications where a nanometer thickness is required, for example in the field of biomedical microdevices.

In generating inert surfaces that are resistant to protein adsorption, self-assembling monolayers (SAM) of various polymers have been used. For example, surfaces coated with high-density short chain ethylene glycol oligomers having 3 to 6 repeat units have been used to prevent the adsorption of proteins. (Ostuni et al., Langmuir, 5605, 5606, Vol.17, No. 18 (2001)). In addition, SAMs having thin polymeric films covalently bonded thereto have successfully resisted the adsorption of proteins. However, it is very difficult to produce SAMs having a film thickness greater than 5 nm.

Shah et al. Macromolecules 2000, 33, 597-605 (2000), describes the use of atom transfer radical polymerization (ATRP) to grow polymer brushes on monolayers of (BrC(CH₃)₂COO(CH₂)10S)₂ that have been self- assembled onto gold substrates. The polymer brushes act as barriers to wet chemical etchants of gold enabling patterns to be transferred into the gold substrates underlying the brushes.

Chapman et al., Langmuir, 1225-1233, Vol. 17, No. 4 (2001), describes the use of grafting to produce a protein and bacteria resistant surface. In this process, polyamines are reacted with carboxylic anhydride groups contained in the SAMs in order to produce a polymer layer having multiple amino groups, which are then acylated to introduce protein and bacteria resistant functional groups.

Unlike the present invention, the method employed by Chapman et al. does not allow either the thickness, or the polymer chain density of the film that is deposited on the surface of a substrate to be controlled with any appreciable degree of accuracy. The film structure generated by the process of the present invention is depicted in FIG. 5a, whereas the film structure generated by the method according to Chapman et al. is depicted in FIG. 5b. As can be seen in FIG. 5a, the polymer chains of the present invention are not entangled with each other. Such a result is to be expected as the films formed in accordance with the present invention are grown via a process involving single monomer additions. In contrast, as can be seen in FIG. 5b, the polymer chains that are deposited in accordance with the self-assembling technique of Chapman et al., are entangled with each other. Such a result is also to be expected as the self-assembling technique of Chapman et al. causes the polymer chains to be deposited in a random coil configuration. As a result, the present invention enables the thickness of the film to be determined by adjusting either the polymer chain length, or the molecular weight and concentration of the monomer from which the repeat units of the polymer are derived. This process further allows the film thickness to be controlled by the length of time the polymer chains are permitted to grow/polymerize.

Kong et al, Macromolecules, 34, 1837-1844 (2000), describes a process for preparing etching barriers for microlithographic applications. This process involves using atom transfer radical polymerization (ATRP) in conjunction with two different self-assembled monolayers to grow poly(methyl methacrylate)(PMMA) and poly(acrylamide) (PAAM) homopolymer brushes on an initiator coated silicon surface.

Although other polymers have been assembled into monolayers onto substrates so as to produce surfaces resistant to the adsorption of proteins and biological cells, this invention discloses new surface materials, i.e. PEGAA monomers that may be grown through an SATRP process in a stepwise and controlled manner on SAMs comprising initiator molecules and optionally spacer molecules. By using this process, a polymeric PEGAA film having the desired thickness can be easily grown on the moiety accepting surface of a substrate having any shape. The process according to this invention also enables a polymeric PEGAA film having a particular thickness, or polymer chain density to be efficiently and accurately deposited on any moiety accepting substrate surface, wherein the thickness specified is within the range of from about 0.5 nm to about 5000 nm and the polymer chain density specified is within the range of from about 0.1 to about 100%.

### SUMMARY OF THE INVENTION

This invention concerns a first process for growing PEGAA films on substrates having a moiety accepting surface comprising

(a) contacting at least one initiator molecule with the moiety accepting surface of the substrate to form an initiator coated substrate, said initiator molecule being selected from the group consisting of

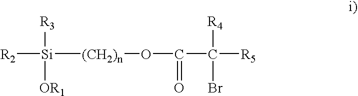

wherein:

n is an integer of 1 to 50;

R, and R₄ are each independently a CH₃, C₂H₅, or an alkyl of

3 to 20 carbons;

R₂ and R₃ are each independently a CH₃, C₂H₅, OR₁, or an

alkyl of 3 to 20 carbons; and

R₅ is a H, CH₃, C₂H₅, or an alkyl of 3 to 20 carbons,

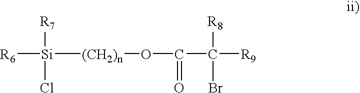

wherein:

n is an integer of 1 to 50;

R₆ and R₇ are each independently Cl, CH₃, C₂H₅, or an alkyl of 3 to 20 carbons;

R₈ is a CH₃, C₂H₅, or an alkyl of 3 to 20 carbons; and

R₉ is a H, CH₃, C₂H₅, or an alkyl of 3 to 20 carbons, and

iii) mixtures thereof; and

(b) further contacting the initiator coated substrate with at least one polyethylene glycol alkyl acrylate monomer in solution, wherein said polyethylene glycol alkyl acrylate monomer has the general formula

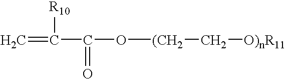

wherein:

n is an integer of 1 to 100; and

R₁₀ and R₁₁ are each independently H, CH3, C₂H₅, or an alkyl of 1 to 20 carbons,

further wherein at least one catalyst and optionally at least one ligand are added to the solution containing the polyethylene glycol alkyl acrylate monomer.

This invention also concerns a second process for growing polyethylene glycol alkyl acrylate films on substrates in which step (a) of the first process further involves contacting the moiety accepting surface of the substrate with a spacer molecule.

This invention also relates to a substrate having a moiety accepting surface that is coated in accordance with either the first, or second process of growing a polyethylene glycol acrylate film.

This invention further relates to a biologically resistant device having deposited thereon a first polymeric composition comprising

(a) at least one initiator molecule selected from the group consisting of

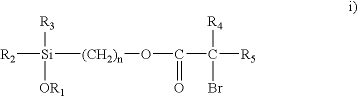

wherein:

n is an integer of 1 to 50;

R₁ and R₄ are each independently a CH₃, C₂H₅, or an alkyl of 3 to 20 carbons;

R₂ and R₃ are each independently a CH₃, C₂H₅, OR₁, or an alkyl of 3 to 20 carbons; and

R₅ is a H, CH₃, C₂H₅, or an alkyl of 3 to 20 carbons,

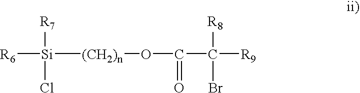

wherein:

n is an integer of 1 to 50;

R₆ and R₇ are each independently Cl, CH₃, C₂H₅, or an alkyl of 3 to 20 carbons;

R₈ is a CH₃, C₂H₅, or an alkyl of 3 to 20 carbons; and

R₉ is a H, CH₃, C₂H₅, or an alkyl of 3 to 20 carbons, and

iii) mixtures thereof; and

(b) at least one polyethylene glycol alkyl acrylate monomer having the general formula

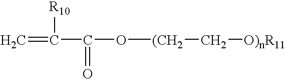

wherein:

n is an integer of 1 to 100; and

R₁₀ and R₁₁ are each independently H, CH3, C₂H₅, or an alkyl of 1 to 20 carbons.

This invention also relates to a biologically resistant device, in which the first polymeric composition further comprises a spacer molecule.

This invention also relates to generating inert surfaces in a variety of applications including, but not limited to, biomedical implant devices, e.g., intraocular lenses, biomedical microdevices, membrane-related appliances, prosthetic devices, biosensors, enzyme-linked immunosorbent assay (ELISA) substrates, medical devices, e.g., contact lenses, stents, catheters, patterned cell culture systems, tissue engineering materials, microfluidic and analytical system materials, drug delivery devices, high throughput screening systems that use proteins or cells, and food packaging materials.

### BRIEF DESCRIPTION OF THE FIGURES

FIG. 1 shows an initiator molecule that is self-assembled into a monolayer on the surface of a substrate.

FIG. 2 shows the growth of a PEGAA film on a substrate using the SATRP process

FIG. 3 shows the self-assembly of a monolayer containing spacer and initiator molecules onto the surface of a substrate.

FIG. 4 shows the bonding of PEGAA polymer chains to the initiator molecules contained in a SAM comprised of both initiator and spacer molecules

FIG. 5a shows vertically deposited polymer chains according to the SATRP process of the present invention.

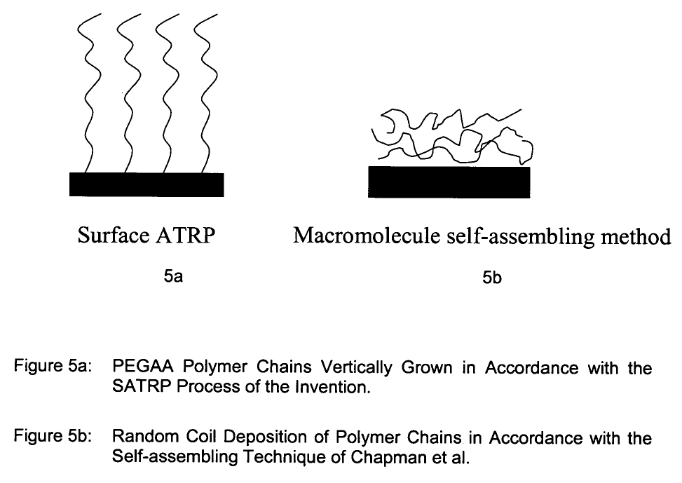

FIG. 5b shows the randomly coiled configuration of polymer chains deposited in accordance with the SAM technique of Chapman et al.

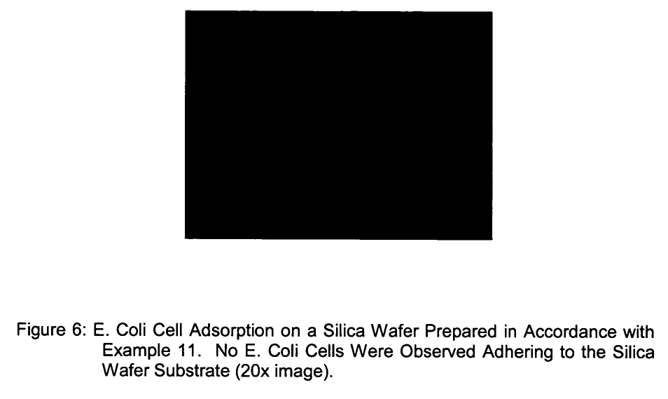

FIG. 6 is a Spot 2 cooled CCD digital camera image at 20× magnification showing no E. coli cells adsorbed to a silica wafer prepared in accordance with Example 11.

FIG. 7 is a Spot 2 cooled CCD digital camera image at 20× magnification showing E. coli cells densely bound to a silica wafer coated with the initiator monolayer of Example 4.

FIG. 8 is a Spot 2 cooled CCD digital camera image at 100× magnification showing E. coli cells densely bound to a silica wafer coated with the initiator monolayer of Example 4.

FIG. 9 is a Spot 2 cooled CCD digital camera image at 20× magnification showing no E. coli cell adsorption on a silica wafer coated with a 20 nm thick PEGM polymer in accordance with the process of Example 5.

FIG. 10 is the schematic of a test cell for protein and cell binding experiments.

FIG. 11 is a cartoon depicting chemical group(s) attached to the surface of polymer chains grown on a substrate.

FIG. 12 is depicting the molecular structures of exemplary spacer molecules.

### DETAILED DESCRIPTION OF THE INVENTION

The term “grow” and any variation thereof, such as “grown” or “growing” is used herein in the same way that the term “polymerizing” is commonly used. More precisely, the term grow describes the chemical reaction by which two or more small molecules (monomers) are combined to from larger or longer molecules (polymers, macromolecules) that contain repeating structural units of the original molecules and have the same percentage composition as the small molecules, if the small molecules were of the same composition.

The process of the present invention utilizes a SATRP process to grow a thin PEGAA film on the moiety accepting surface of a substrate in order to produce a protein and biologically cell resistant surface that is useful in many commercial applications including, but not limited to biomedical implant devices, e.g., intraocular lenses, biomedical microdevices, membrane-related appliances, prosthetic devices, orthopedic implantable devices, biosensors, enzyme-linked immunosorbent assay (ELISA) substrates, medical devices, e.g. contact lenses, stents, and catheters, patterned cell culture systems, tissue engineering materials, microfluidic and analytical system materials, drug delivery devices, high throughput screening systems that use proteins or cells, food packaging materials, hygienic products, and electronic materials, e.g. electrical insulation layer.

The SATRP process utilized in the present invention is generally described in “Functional Polymers by Atom Transfer Radical Polymerization” by Coessens, et al., Progress in Polymer Science 26 (2001) 337-377 hereby incorporated by reference. Specifically, the present invention involves growing a thin PEGAA film on the moiety accepting surface of a substrate by contacting the substrate surface with at least one initiator molecule, and then further contacting, in the presence of at least one catalyst and optionally at least one ligand, the surface of the substrate with a PEGAA monomer in solution. Optionally, the moiety accepting surface of the substrate is first contacted with a mixture of initiator and spacer molecules, and then further contacted, in the presence of at least one catalyst and optionally at least one ligand, with a PEGAA monomer in solution.

The substrate surfaces onto which the thin PEGAA films of the present invention can be grown include any substrate that has a surface capable of accepting at least one moiety. Examples of such substrates include, but are not limited to glass, metal oxide, silicon, fabrics, porous substrates, quartz, polymeric substrates reinforced with other inorganic material, zirconia and polymeric resins. The substrate may also take any desired size or shape, such as a square, a round flat chip, or a sphere.

As is generally known in the art, the surface of the substrate will contain a moiety accepting group, such as for example hydroxyl groups, thiol groups, carboxyl groups or mixtures thereof. The density of these moiety accepting groups is a function of the type of substrate being used, as well as, any steps of preparation that involve exposing the surface of the substrate to chemicals. For example, using known techniques, such as those involving acids, the surface of the substrate can be cleaned and left in a hydrophilic state. Moiety accepting groups may also be introduced onto the surface of the substrate by being exposed to chemicals, corona discharge, plasma treatment, etc. For example, piranha solution can be used to hydroxylate the surface of a silicon substrate. Some substrates may have moiety accepting groups available on their surface that are intrinsic to the substrate.

In general, the initiator molecules that may be used in accordance with the invention include, but are not limited to, those having the following formulas:

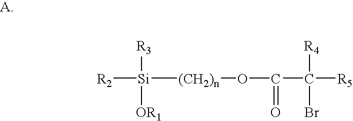

where R₁ is a CH₃, C₂H₅, or an alkyl of 3 to 20 carbons; R₂ is a CH₃, C₂H₅, OR₁, or an alkyl of 3 to 20 carbons; R₃ is a CH₃, C₂H₅, OR₁, or an alkyl of 3 to 20 carbons; R₄ is a CH₃, C₂H₅, or an alkyl of 3 to 20 carbons; R₅ is a H, CH₃, C₂H₅, or an alkyl of 3 to 20 carbons, and n is an integer of 1 to 50; and

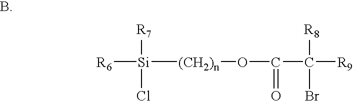

where R₆ is a Cl, CH₃, C₂H₅, or an alkyl of 3 to 20 carbons; R₇ is a Cl, CH₃, C₂H₅, or an alkyl of 3 to 20 carbons; R₈ is a CH₃, C₂H₅, or an alkyl of 3 to 20 carbons; R₉ is a H, CH₃, C₂H₅, or an alkyl of 3 to 20 carbons, and n is an integer of 1 to 50.

However, the preferred initiator molecule is 5′-(triethoxylsilylpentyl) 2-bromo-2-methylpropionatecan and can be prepared for assembly onto the surface of a hydroxylated substrate in accordance with the following reaction scheme. First, the formula (I) 1,2-dibromo, 2-methyl propanoic acid is reacted with the formula (II) 5-hexen-1-ol to produce the formula (III) intermediate compound pent4′-enyl-2-bromo-2-methyl propionate.

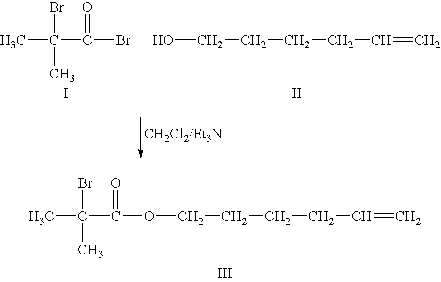

The formula III intermediate compound is then reacted in the presence of at least one catalyst and optionally at least one solvent, as set forth herein below, with formula (IV) triethoxysilane to produce the formula (V) initiator 5′-(triethoxylsilylpentyl) 2-bromo-2-methylpropionate.

The solvents optionally used in synthesizing initiator molecules includes polar solvents, such as alcohol, acetone, and methanol, and nonpolar solvents, such as dry organic solvents, e.g., toluene, hexene, and heptane. Preferably, however, nonpolar solvents are used.

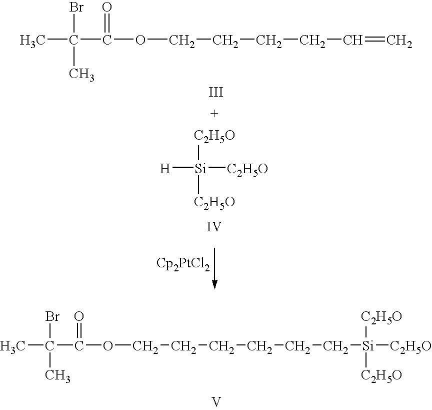

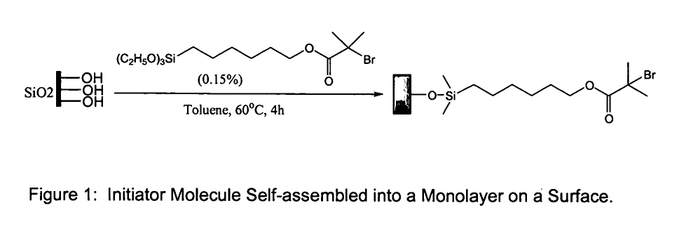

As further illustrated in FIG. 1, the formula (V) initiator molecules are then assembled as a monolayer onto the hydroxylated surface of the substrate. A person of ordinary skill in the art, however, would know how to modify this reaction scheme in order to accommodate the assembly of initiator molecules onto other moiety accepting substrate surfaces, such as for example a substrate surface having thiol or carboxyl groups attached thereto. A person of ordinary skill in the art would also recognize that this is just one of the many available ways for preparing initiator molecules useful in the process of this invention.

The initiator molecules can be assembled as monolayers onto the moiety accepting surface of a substrate in the absence or presence of variously readily available solvents. Other methods for assembling the initiator molecules onto the surface of the substrate are well known to those skilled in the art, such as for example vapor deposition.

The species of solvents that can optionally be used is not particularly restricted, includes the following examples: water; hydrocarbon solvents, such as toluene and benzene; ether solvents, such as diethyl ether and terahydrofuran; halogenated hydrocarbon solvents, such as methylene chloride and chloroform; ketone solvents, such as acetone, methyl ethyl ketone and methyl isobutyl ketone; alcohol solvents, such as methanol, ethanol, propanol, isopropanol, n-butyl alcohol and tert-butyl alcohol; nitrile solvents, such as acetonitrile, propionitrile and benzonitrile; ester solvents, such as ethyl acetate and butyl acetate; carbonate solvents, such as ethylene carbonate and propylene carbonate; inorganic solvents; and mixtures of water and organic solvents. However, nonpolar solvents are preferably used. These solvents may be used alone or in combination as an admixture and are readily available commercially. For example, toluene, and the other listed solvent, can be readily obtained from Aldrich Chemical Co., P.O. Box 2060, Milwaukee, Wis., 53201.

The percentage by volume of solvent optionally used in assembling the initiator molecules on the substrate surface ranges from about 0.05% to about 25%, preferably from about 0.1% to about 5%. The initiator molecules are assembled onto the substrate surface at a temperature ranging from 0° C. to about 130° C., preferably from room temperature to about 100° C. The substrate surface is exposed to initiator molecules for a period of time ranging from about 1 minute to about 1 week, preferably from about 5 minutes to about 60 minutes.

Furthermore, the surface density of the initiator molecules, and hence the potential surface density of the PEGAA polymers grown thereon, ranges from 0.1 to 100%, more preferably 5% to 100%, and most preferably 25% to 100%. The surface density of the initiator molecules is defined either as the number of initiator molecules contained per unit cm² on the surface of a substrate, or as the percent of the total surface area occupied by the initiator molecule when the SAM is comprised of both initiator and spacer molecules.

After the initiator molecules, and optionally the spacer molecules, are assembled onto the surface of the substrate, the substrate is preferably cured sufficiently to permit complete covalent bonding of the initiator molecules to the substrate, for example, by heating, preferably to a temperature ranging from about 100° C. to about 180° C. for a time period, ranging preferably from about 30 minutes to about 10 hours, and more preferably for a time period of about 1 hour. Other methods of curing that are sufficient to permit complete covalent bonding of the initiator molecules to the substrate will be apparent to those skilled in the art. The level of curing will contribute to the stability of the final film.

The prepared substrate surface is then reacted with at least one PEGM monomer. The PEGAA monomers that may be used in accordance with the present invention include, but are not limited to PEGAAs having the following general formula:

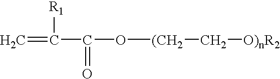

where R₁ is a H, CH3, C₂H₅, or an alkyl of 1 to 20 carbons, preferably 1 to 10 carbons, most preferably 1 to 5 carbons; R₂ is a H, CH3, C₂H₅, or an alkyl of 1 to 20 carbons, preferably 1 to 10 carbons, most preferably 1 to 5 carbons and n is an integer of 1 to 100. However, polyethylene glycol methacrylate (PEGM) is preferred.

PEGAA monomers are readily available commercially. For example, PEGM can be obtained from Aldrich Chemical Co., P.O. Box 2060, Milwaukee, Wis., 53201.

Suitable catalysts that can be used in reacting the PEGAA monomers with the prepared substrate surface include, but are not limited to metal complexes that contain an element from group 7, 8, 9, 10, 11 of the periodic table as the central metal atom in the metal complex. Preferably, the central metal atom is copper, nickel, ruthenium or iron, and in particular, monovalent copper, divalent ruthenium and divalent iron is more preferred as the central metal atom. However, copper is most preferred as the central metal atom. Examples of the copper containing catalysts preferably used include cuprous chloride, cupric chloride, cuprous bromide, cuprous iodide, cuprous cyanide, cuprous oxide, cuprous acetate, cuprous perchlorate and the like. However, the copper catalysts most preferably used are cuprous chloride and cupric chloride. The ratio of cuprous chloride (copper (I) chloride) to cupric chloride (copper (II) chloride) ranges from 0.1 to 100, more preferably from 2:1 to 50:1, and most preferably from 3:1 to 10:1.

Furthermore, if a copper compound is used, a ligand, such as 2,2′-bipyridyl or a derivative thereof, 1,10-phenanthroline or a derivative thereof, and an alkylamine, such as tributylamine or a polyamine, such as tetramethylethylenediamine, pentamethyldiethylenetriamine and hexamethyltriethylenetetraamine, is added to enhance the catalytic activity.

A tristriphenylphosphine complex of divalent ruthenium (RuCl₂(PPh₃)₃), as well as, a tristriphenylphosphine complex of divalent iron (FeCl₂(PPh₃)₃) are also well suited for use as the catalyst. When the tristriphenylphosphine complex of divalent ruthenium is used as the catalyst, an aluminum compound, such as trialkoxyaluminum is added to increase the activity of the catalyst.

Polar solvents, such as water, or other suitable liquids or solvents, such as organic solvents, e.g. acetone and methanol, or mixtures thereof can also be added to the solution containing the PEGAA monomers. Preferably, however, water is added. The concentration of the PEGAA monomer solution, whether additional liquids or solvents are added thereto or not, will preferably range from about 5% to about 100% and more preferably from about 40% to about 70%. Furthermore, the molar ratio of catalyst to PEGAA monomer ranges from 1:5 to 1:500 and more preferably from 1:20 to 1:100, and the molar ratio of ligand to catalyst preferably ranges from 1:2 to 1:3.

The PEGAA film is grown on the substrate preferably at a temperature ranging from about 0° C. to about 150° C., more preferably at a temperature ranging from room temperature to about 50° C., and most preferably at room temperature.

When the substrate surface is subsequently exposed to the solution of PEGAA monomers, the PEGM monomers form covalent bonds with the initiator molecules. As a result, the density of the initiator molecules that are contained on the moiety accepting surface of the substrate can be used to control the density of the PEGAA chains grown on the surface. However, although the surface density of the initiator molecules will determine the density of the PEGAA polymer chains, the PEGAAs occupy more space than the initiators, and therefore the surface density of the PEGAA will not necessarily directly correspond to the surface density of the initiator molecules. As a result, from about 0.1 to about 100% of the surface of the substrate will contain PEGAA chains, more preferably from about 25 to about 100% of the surface of the substrate will contain PEGAA chains, and most preferably from about 75 to about 100% of the surface of the substrate will contain PEGAA chains. In other words, the polymer chain density on the substrate surface ranges from 10⁻⁵˜5.0 μmol/m². Accordingly, the process of the invention enables a PEGAA film to be grown on a moiety accepting substrate in a controlled and stepwise manner, so that PEGAA films having a specific thickness ranging from about 0.5 nm to about 5000 nm, preferably from about 5 nm to about 250 nm, most preferably from about 5 nm to about 100 nm can be produced.

The growth of the PEGAA polymer chain is also affected by both the concentration of the PEGAA to which the substrate is exposed, and the length of time the PEGAA chain is allowed to polymerize/grow. As a result, the polymer film can be grown to a specific thickness by also controlling either the concentration of the PEGAA, or the length of time the PEGAA chain is permitted to grow/polymerize.

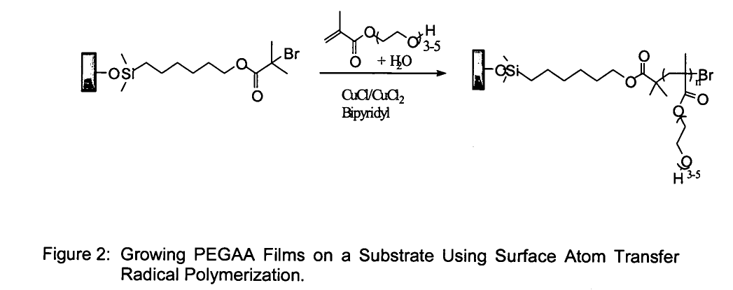

FIG. 2 further illustrates the two-step process of the invention involving first the self-assembly of a monolayer containing initiator molecules, and then the growth via SATRP of PEGAA film.

In a further process of the present invention, the moiety accepting surface of the substrate can be contacted in step (a) with a mixture of initiator molecules, as set forth hereinabove, and spacer molecules. Examples of spacer molecules that can be used in accordance with the invention include but are not limited to the following:

(a) alkyl chains having the following general formulas

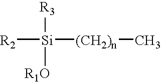

wherein:

n is an integer of 1 to 50;

R₁ is a CH₃, C₂H₅, or an alkyl of 3 to 20 carbons;

R₂ and R₃ are each independently a CH₃, C₂H₅, OR₁, or an alkyl of 3 to 20 carbons and

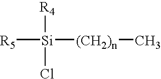

wherein:

n is an integer of 1 to 50;

R₄ and R₅ are each independently Cl, CH₃, C₂H₅, or an alkyl of 3 to 20 carbons;

(b) phenyl and phenyl derivatives having the following general

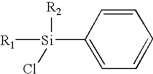

formula

wherein:

R₁ and R₂ are each independently Cl, CH₃, C₂H₅, or an alkyl of 3 to 20 carbons; and

(c) a mixture of alkyl chains and functional groups having the following general formula

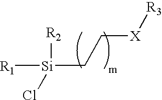

wherein:

m is an integer of 1 to 50;

R₁ and R₂ are each independently Cl, CH₃, C₂H₅, or an alkyl of 3 to 20 carbons;

R3 is a phenyl, OH, NH2, or an alkyl of 3 to 20 carbons, and X is an O, COO, or a CONH.

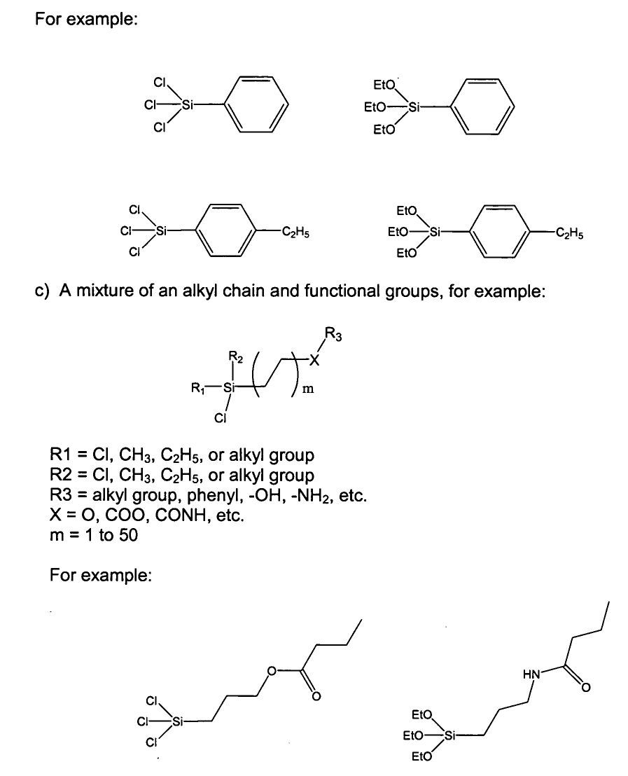

Exemplary spacer molecules are further provided in FIG. 12

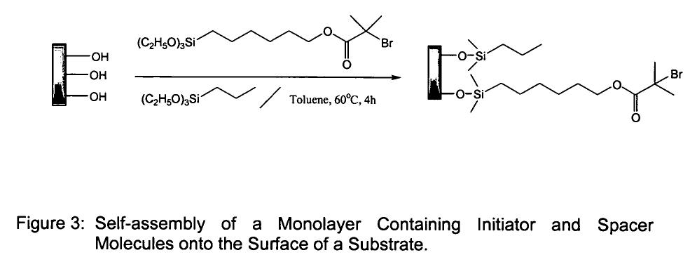

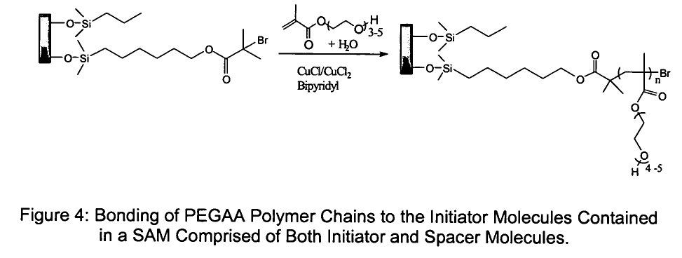

However, triethoxylpropylsilane is preferably used as the spacer molecule. FIG. 3 demonstrates the deposition of a SAM comprising an initiator molecule, such as 5′-(triethoxylsilylpentyl) 2-bromo-2-methylpropionate, and a spacer molecule, such as triethoxylpropylsilane onto the hydroxylated surface of a substrate. FIG. 4 further demonstrates the growth of a PEGM film in a controlled and stepwise manner on a SAM comprised of both spacer and initiator molecules.

When the SAM is comprised of both spacer and initiator molecules it is important to note that the PEGAA monomers are only bound to the initiator molecules, and not to the spacer molecules. The spacer molecules simply perform the role of neutral space-holders, thereby enabling the density of the PEGAA monomers that are being grown on the surface of the substrate to be controlled. The relative concentration of surface-bound initiator molecules to surface-bound spacer molecules can be selected based on the density of PEGM desired or needed for a particular application. In general, the ratio of initiator molecules to spacer molecule ranges from 95:5 mol % to 1:99 mol %. However, some embodiments use 100 mol % of the initiator molecules and 0 mol % of the spacer molecules.

By utilizing the SATRP process to apply thin PEGAA films to substrates, termination reactions are eliminated, which in turn results in the polydispersity index being lowered. Lowering the polydispersity index enables the molecular weight of the polymers to be controlled by controlling the concentration of the monomer, which relies on the equilibrium of the dormant and the active chain ends of the growing polymeric molecules, wherein equilibrium prefers the dormant chain ends.

This invention further allows chemical groups that are attached to PEGAA polymer chains available on the surface of the thin PEGAA films grown in accordance with the SATRP process of the present invention, to be further modified with specific functional groups, which enables the modified chemical groups to be utilized in additional applications or utilities. Polymer chains that are modified by attaching additional functional groups to their surfaces are called polymer brushes. For example, the polymer chains contained in the PEGM film could be further modified by having biological ligands designed to recognize specific proteins attached to their surface. Polymer brush formation can be better understood by referring to “Synthesis of Nanocomposite Organic/inorganic Hybrid Materials Using Controlled/“Living” Radical Polymerization” by Pyun, et al., Chem. Mater. 2001, 13, 3436-3448, which is hereby incorporated by reference.

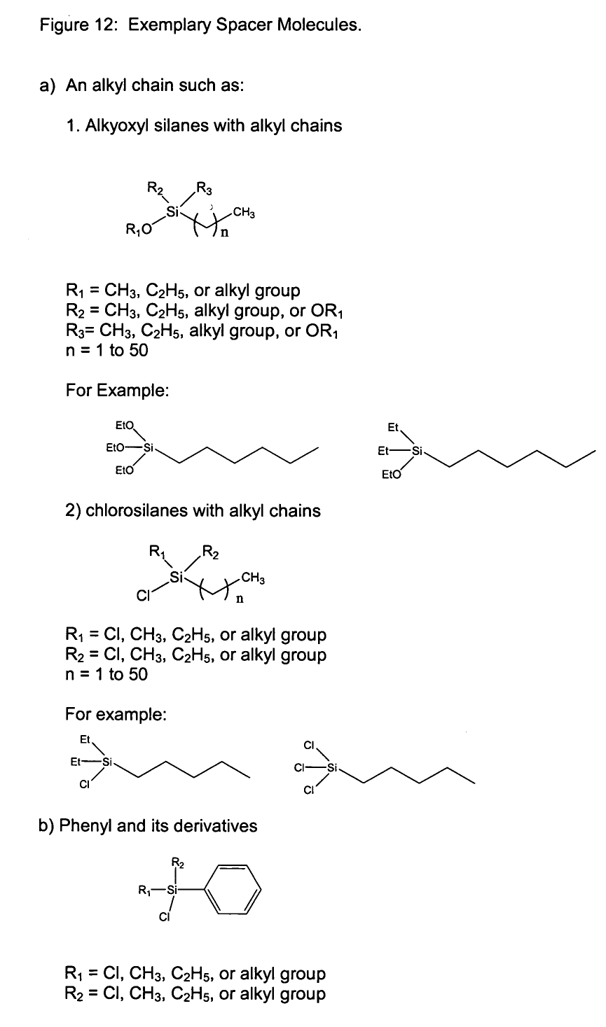

FIG. 11 depicts a substrate surface that has PEGAA polymer chains, which have been grown on the surface in accordance with the process of the invention, attached thereto. As is evidenced by FIG. 11, the PEGAA chains have Br and OH chemical groups capable of reacting with various functional groups attached to their surface. More specifically, the surface of the PEGAA film deposited in accordance with the process of the invention can be 1) converted to a negatively charged surfaces by reacting the chemical group(s) attached thereto with functional groups, such as COOH, SO₃H, PO₄, etc.; 2) converted to a positively charged surface by reacting the chemical group(s) attached thereto with functional groups such as, NR₃, NH₂, DNA, etc., in order, for example, to produce a surface capable of killing bacteria; 3) converted to a biological ligand by reacting the chemical group(s) attached thereto with functionalized ADP, ATP, NADH, etc. in order, for example, to facilitate bioseparation processes; 4) lined with biological entities by reacting the chemical group(s) attached thereto with functionalized proteins, peptides, DNA, etc. in order, for example, to facilitate the discrimination or sorting of cells; and 5) linked with surface modified particles, such as metal nanoparticles, e.g. gold, silver, and copper and semiconductor nanoparticles, e.g. CdSe and ZnO in order, for example, to form metal-organic hybrid nanomaterials useful in the electronics and optics industries. PEGAA film surfaces that are modified as set forth hereinabove can then be utilized, for example, as the surface material of a biological sensor. Biological sensors can be produced using standard techniques as generally described in U.S. Pat. App. No. 2002/0001845, which is hereby incorporated by reference.

### EXPERIMENTAL

The present invention is further defined in the following Examples, in which all parts and percentages are by weight. It should be understood that these Examples are given by way of illustration only. From the above discussion and this Example, one skilled in the art can ascertain the essential characteristics of this invention, and without departing from the spirit and scope thereof, can make various changes and modifications of the invention to adapt it to various uses and conditions.

In accordance with the Examples, the following materials were used:

Singly polished undoped silicon wafers obtained from Silicon Valley Microelectronics, Inc. (San Jose, Calif.) having a thickness of 330-381±50 μm.

n-Propyl triethoxysilane was obtained from Gelest, Inc. (Morrisville, Pa.).

Initiator molecule: (5-Trichlorosilylpentyl) 2-bromo-2-methyl propionate with a general formula of (EtO)₃Si(CH₂)₆OCOC(CH₃)₂Br. This compound was synthesized in a laboratory at DuPont Central R&D.

The following materials which were purchased from Aldrich Chemical Co., P.O. Box 2060, Milwaukee, Wis., 53201:

Polyethylene glycol methacrylate (Average MW 360)

Bipyridine

Copper(I) chloride (CuCl)

Copper(II) chloride (CuCl₂)

5-hexen-1 -ol

Triethylamine

HSi(OCH₂CH₃)₂

CP₂PtCl₂

2-bromo-2-methylpropionyl bromide

Toluene

Other organic solvents such as methylene chloride

### EXAMPLE 1

### Synthesis of Pent4-enyl-2-bromo-2-methyl propionate Precursor

With continuous stirring, 1.46 mL of 5-hexen-1-ol (30.0 mmol) and 5.00 mL of triethylamine (30.0 mmol) were added at 0° C. and under a nitrogen gas atmosphere to a flask containing 16 mL of dry CH₂Cl₂. 8.27 mL of 2-bromo-2-methylpropionyl bromide (30.0 mmol) was added dropwise over 10 min to form a white triethylamine salt. The resulting solution was then stirred for 1 hour at 0° C. The solution was warmed to room temperature over the next 2.5 hours, and became darker brown in color. The precipitate was filtered off and rinsed with 50 mL methylene chloride. The filtrate was extracted 4 times with saturated aqueous ammonium hydroxide (NH₄Cl) and 4 times with H₂O. The crude brown oil was characterized and used in the next step of synthesis. HNMR (CDCl₃, δ in ppm): 5.9-6.0 (m, 1H), 5.1-5.2 (d, 2H), 4.3 (m, 2H), 2.2 (m, 2H), 2.1 (s, 6H), 1.8 (m, 2H), 1.6 (m, 2H). Mass Spectrum (Cl): m/z 248.

### EXAMPLE 2

### Preparation of 5-Triethoxyl silyl Pentyl 2-bromo-2-methyl propionate Initiator

In a flask equipped with a reflux condenser and a nitrogen purge, 0.698 g of pent-4′-enyl-2-bromo-2-methyl propionate (2.80 mmol) prepared in accordance with Example 1, 2 mL of HSi(OCH₂CH₃)₂ (10.8 mmol), and 5.0 mg CP₂PtCl₂ (0.0125 mmol) were added to 5 mL of dry CH₂Cl₂ solvent and then stirred. The reaction was refluxed overnight in the dark. After 17 hrs of refluxing, the reaction mixture was cooled and the solvent and excess silane were removed under reduced pressure. The crude product was distilled (at 60 millitorr vacuum/ 135° C.) to yield a light brown oil product (62% overall yield). ¹H NMR (CDCl₃, δ in ppm): 4.10-4.13 (t, 2H), 3.75-3.79 (q, 6H), 1.89 (s, 6H), 1.64 (m, 2 H), 1.35, (m, 6H), 1.17-1.21 (t, 9H), 0.59 (m, 2H). MS (Cl): m/z 430 (M+NH₄), 412 (M+H), 384 (M−C₂H₅), 367 (M−C₂H₅O), 287, 245,180.

### EXAMPLE 3

### Alternative Preparation of 5-Triethoxyl silyl pentyl 2-bromo-2-methyl propionate Initiator

In accordance with the process of Example 2, 5-Triethoxyl silyl pentyl 2-bromo-2-methyl propionate was prepared using H₂PtCl₆ as the catalyst instead of Cp₂PtCl₂. Since this catalyst showed good solubility in the reagents used, the reaction was run without using any solvent. The distilled product had the same spectral data as the Initiator produced in Example 2, with a yield near 65%.

### EXAMPLE 4

### Self-Assembling Initiator Monolayer on Silicon Substrate

Step 1: Silicon Surface Clean-up

The silicon wafers were cut into pieces of 24×30 mm² or 20×15 mm². Two special wafer holders (glass trays were designed for this purpose. Each of the holders can accommodate up to 10 wafers). The wafers were treated with piranha solution (70% H₂SO₄+30% H₂O₂ (30% concentrate)) in a beaker for 30 min at 70° C. The wafers were then rinsed thoroughly with the Barnstead Nano-pure water (18.2 MΩ-cm), and dried in oven at 120° C. for 1 h.

The piranha solution should be handled with extreme caution, as it tends to violently react with most organic materials. There should not be organic materials present in the area where the piranha solution is being used. The operator handling the piranha solution should be equipped with double safety gloves, for example, nitrile and neoprene, and should exercise any additional safety precautions that are warranted.

Step 2: Self-Assembling a 0.15% Solution of Initiator Molecules as a Monolayer

In preparing 150 mL of 0.15% 5-Triethoxyl silyl pentyl 2-bromo-2-methyl propionate, 0.225 mL of the 5-Triethoxyl silyl pentyl 2-bromo-2-methyl propionate Initiator prepared in accordance with either example 2 or 3 was added to 150 mL dried toluene, and stirred for 5 minutes. The solution was then transferred to a shallow beaker loaded with 40 pieces of clean wafers (15×20 mm² or 24×30 mm²). The beaker was covered with aluminum foil and heated for four hours in an oil bath at 60° C. The reacted wafers were then rinsed with toluene and acetone, and baked in an oven at 110° C. for 1 hour. After baking, the film thickness of the assembled initiator monolayer was measured with an ellipsometer and determined to be 10.3 Å.

### EXAMPLE 5

### Growing a Polyethylene Glycol Methacrylate (PEGM) Film on the Surface of a Silicon Substrate

In a typical reaction, a PEGM monomer mixture having a 1.5M concentration was prepared by adding 6.0 g of PEGM (MW 360) and 5.0 g of nanopure water to a 50 mL round-bottom flask. Then, 0.075 g of bipyridyl, 0.0054 g of CuCl₂ and 0.02 g CuCl were added to the flask under a nitrogen atmosphere. The flask was sealed with a rubber septum and the mixture was stirred for 10 min under a nitrogen atmosphere. 5 mL of said mixture was transferred by syringe to a flask charged with a wafer having an initiator monolayer assembled on the surface thereof in accordance with Example 4. The flask containing the wafer was flushed with N₂ for 5 minutes and then sealed with a rubber stopper before charging of the chemicals. The reaction was allowed to continue for a period of time ranging from 15 minutes to 72 hours depending on the film thickness desired. Thereafter, the wafer was rinsed with nanopure water and air-dried.

Subsequently, the thickness of the PEGM thin film was measured by an ellipsometer. Please see Table 1 contained herein below. For each of the measurements, the relative standard deviation (%RSD) is less than 3% indicating that the film surface is very uniform. In addition, the film thickness vs. reaction time is fitted with the following linear relationship: y=48.1x+79. Within 8 hours the PEGM film grows to 44.7 nm. The low relative standard deviation of the PEGM layer thickness is less than 10% indicating that the thickness of the PEGM layer can be very well controlled by the amount of time the PEGM layer is permitted to grow.

TABLE 1
PEGM Film Growth in Correlation to
Polymerization Reaction Time.

| T (h) | Thickness (Å) | St. Dev (Å) |
|---|---|---|
| 0.5 | 81.4 | 6.5 |
| 1 | 128.2 | 5.1 |
| 2.5 | 210 | 21.3 |
| 4 | 293.3 | 14.2 |
| 6 | 372.7 | 23.3 |
| 8 | 447.6 | |

### EXAMPLE 6

### Dependence of PEGM Film Growth on Monomer Concentration

The rate at which a PEGM film is grown on the surface of a substrate was found to depend on the rate of polymerization/growth, which in turn was found to depend on the concentration of the monomer in solution. A PEGM monomer mixture having a 2.1M concentration was prepared by adding 6.0 g of PEGM (MW 360) and 2.0 g of nanopure water to a 50 mL round-bottom flask. Then, 0.075 g of bipyridyl, 0.0054 g of CuCl₂ and 0.02 g CuCl were added to the flask under a nitrogen atmosphere. The flask was then sealed with a rubber septum.

A PEGM monomer mixture having a 1.5M concentration was prepared in accordance with Example 5, and then sealed inside the flask with a rubber septum.

After stirring both mixtures for 10 min under a nitrogen atmosphere, 5 mL of each mixture was transferred to separate 50 mL round-bottom flasks containing a wafer having an initiator monolayer in accordance with Example 4 assembled on its surface. Each flask was maintained at a nitrogen atmosphere. The reaction was conducted at room temperature for the periods of time as set forth in Table 2. At the end of each reaction, each wafer was rinsed with nanopure water and air-dried.

TABLE 2
PEGM Film Thickness in Correlation to the Concentration of
Monomer in Solution

| | PEGM Thickness (Å) at | PEGM thickness (Å) at |
|---|---|---|
| Polymerization time | monomer concentration | monomer concentration |
| (h) | (C = 2.1 M) | (C = 1.5 M) |
| 0.5 | | 82.7 |
| 1 | | 127.9 |
| 1.25 | 59.2 | |
| 2.5 | 85.3 | 228.5 |
| 4 | 118.3 | 328.3 |
| 6 | | 399.5 |

### EXAMPLE 7

### Self-Assembling a Monolayer of Both Initiator and Spacer Molecules onto the Surface of a Substrate

(a) Preparing a SAM Having an Initiator/spacer Molar Ratio of 1:1

75 μL of the spacer n-propyl triethoxysilane and 150 μL of the initiator 5-Triethoxyl silyl pentyl 2-bromo-2-methyl propionate, which was prepared in accordance with either example 2 or 3, were combined in a 250 mL flask containing 150 mL of dried toluene. The mixture was stirred for 5 min, and then transferred to a beaker loaded with 20 pieces of clean wafers (1.5×2.0 cm²). The beaker was covered with aluminum foil and heated in an oil bath for 4 hours at 60° C. Then, the wafers were rinsed with toluene and acetone, and baked in an oven at 1 atmosphere at 110° C. for 1 hour.

(b) Preparing a SAM Having an Initiator/spacer Molar Ratio of 1:10

187.5 μL of the spacer n-propyl triethoxysilane and 37.5 μL of the initiator 5-Triethoxyl silyl pentyl 2-bromo-2-methyl propionate were combined in a 250 mL flask containing 150 mL of dried toluene. The procedure recited in Example 7(a) was repeated.

(c) Preparing a SAM Having an Initiator/spacer Molar Ratio of 1:50

216.3 μL of the spacer n-propyl triethoxysilane and 8.6 μL of the initiator 5-Triethoxyl silyl pentyl 2-bromo-2-methyl propionate were combined in a 250 mL flask containing 150 mL of dried toluene. The procedure recited in Example 7(a) was repeated.

(d) Preparing a SAM Having an Initiator/spacer Molar Ratio of 1:100

220.6 μL of the spacer n-propyl triethoxysilane and 4.4 μL of the initiator 5-Triethoxyl silyl pentyl 2-bromo-2-methyl propionate were combined in a 250 mL flask containing 150 mL of dried toluene. The procedure recited in Example 7(a) was repeated.

### EXAMPLE 8

### Using SATRP to Control the Chain Density of a PEGM Film

The density of the polymers chains grown on the surface of a substrate is controlled by the density of the initiator molecules contained in the SAMs having initiator:spacer ratios, for example of 1:1, 1:10, 1:50 and 1:100. Accordingly, the wafers prepared in accordance with Example 7, were further contacted with PEGM in accordance with the process of Example 5. More specifically, a solution having a PEGM monomer concentration of 1.5M, was prepared by adding 6.0 g of PEGM (MW 360) and 5.0 g of nanopure water to a 50 mL round-bottom flask. Then, 0.075 g of bipyridyl, 0.0054 g of CuCl₂ and 0.02 g CuCl were added to the flask under a nitrogen atmosphere and the flask was sealed with a rubber septum.

After stirring the mixture for 10 min under a nitrogen atmosphere, 5 mL of the mixture was transferred to different 50 mL round-bottom flasks each of which contained a wafer prepared in accordance with examples 7(a), (7(c) and 7(d). A nitrogen atmosphere was maintained in the flask. The reaction was conducted at room temperature for the desired period of time. At the end of the reaction, each wafer was rinsed with nanopure water and air-dried.

### EXAMPLE 9

### Ellipsometrically Measuring the Thickness of the PEGM Film

The thickness of the initiator monolayer 5-Triethoxyl silyl pentyl 2-bromo-2-methyl propionate in combination with the PEGM film grown on the surface of the silicon wafers in accordance with Example 8 was measured by a null-ellipsometer (Rudolph Auto EL-II, Fairfield, N.J.). The wavelength of the laser beam employed for the measurement was 632.8 nm, and the angle of incidence was 70°. The refractive index of PEGM was estimated to be 1.54. The thickness was reported as an average of ten measurements on a given sample of film. The oxide layer (SiO₂) on the bare silicon wafer was determined to be 18.2 Å thick. The thickness of the PEGM film layer in combination with the initiator monolayer was obtained by subtracting the contribution of the oxide layer.

TABLE 3
Comparing PEGM Film Thickness with the Surface Density of
Initiator Deposited on the Surface of the Substrate.

| | PEGM film | PEGM film | |
|---|---|---|---|
| | thickness | thickness | PEGM film thickness |
| Polymerization | (Å) | (Å) | (Å) |
| time (h) | (50% initiator) | (2% initiator) | (1% initiator) |
| 0.5 | 83.7 | 56.1 | 49.2 |
| 1 | 127.9 | 81.9 | 73.4 |
| 2.5 | 228.5 | 140.1 | 125.3 |
| 4 | 328.3 | 203.7 | 178.1 |
| 6 | 399.5 | 250.9 | 241.3 |

### EXAMPLE 10

### Adhesion of Protein to a PEGM-Coated Silicon Wafer

Materials:

Fibrinogen was obtained from Sigma Aldrich Chemical Company, St. Louis, Mo. Buffer solutions having an ionic strength of 0.1 M and 1.0 M were separately prepared by dissolving 0.1 M and 1.0 M potassium dihydrogen phosphate (KH₂PO₄) in Milli Q water, and then titrating with sodium hydroxide (NaOH) to a pH of 6.0.

All experiments were performed in triplicate.

Methods:

(a) Preparing a 0.1 M buffer solution and a 1.0 M desorption/washing buffer solution.

Both buffer solutions were prepared by dissolving 0.1 M and 1.0 M of potassium

dihydrogen phosphate (KH₂PO₄) in two separate beakers containing Milli Q water, and then titrating each solution with sodium hydroxide (NaOH) to a pH of 6.0.

(b) Preparing the protein containing buffer solution:

Fibrinogen was dissolved in the above buffer solution having a 0.1 M concentration, by stirring the solution for an hour at room temperature.

(c) Silicon wafer handling:

During each experiment, wafers were handled at wafer corners with Teflon-coated tweezers.

(d) Experimental setup:

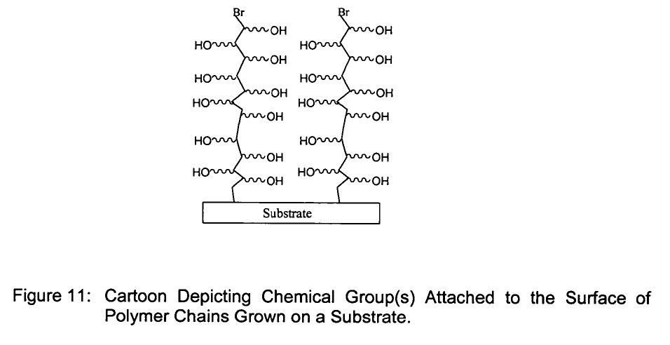

The experimental set-up comprised three beakers, wherein the first beaker contained the protein buffer solution prepared herein above, the second beaker contained the 0.1M buffer solution prepared herein above and the third beaker contained the 1.0M wash buffer solution prepared herein above. FIG. 10 schematically demonstrates the immersion of silicon slides in the protein buffer solution.

This example compared the adsorption of protein to, as well as the desorption of protein from, the surface of three silicon wafers having different surface coatings. Wafer 1 had a bare surface with nothing coated thereon. Wafer 2 was prepared in accordance with Example 4, wherein initiator molecules were self-assembled as a monolayer on the surface of the wafer. Wafer 3 was prepared in accordance with Example 5, wherein a PEGM film was grown on the surface of the wafer.

A. Adsorption of Proteins

Using the Teflon®-coated tweezers, the wafers were placed in a slotted glass tray, and lowered into the protein buffer solution to an elevated position just above the stir bar. The wafers remained immersed in the solution, which continued to be stirred, for 1 hour. After 1 hour, the cradle was removed from the protein solution. While the wafers were still in the cradle, they were rinsed by first being lowered into the second beaker containing the 0.1 M buffer solution. Then, as each individual wafer was removed from the tray with the Teflon® tweezers, it was rinsed again with just Milli Q water and then dried with N₂ flow. After being dried, each wafer was measured to determine the thickness of the protein layer adsorbed thereon.

B. Desorption of Proteins

After being measured, the wafers were placed back into the cradle and submerged in the 1.0 M buffer solution, also known as the desorption solution prepared herein above. After being submerged in the desorption solution for 1 hour, the wafers were once again washed/rinsed and dried in accordance with the procedure outlined herein above. After being dried, each wafer was once again measure to determine the thickness of the protein layer still adsorbed thereon.

Ellipsometry was employed to measure the thickness of the base silica oxide layer, the initiator layer, and the PEGM film layer on the wafers. In addition, the wafers were scanned to determine the thickness of the protein layer. The refractive index of the protein and polymeric coating were assumed to be identical. Variations in the protein packing density can lead to varying loadings even for identical thickness of the polymeric coating on the wafer.

A manual scan was performed at 10 different locations on each wafer, with a quarter turn on the wafer following every scan point. An automated scan was performed at 600 location points on one of the triplicate wafers used for each condition.

For a data analysis determination of the statistical equivalence means of 3 samples using ANOVA, a 10-point scan is done on every wafer sample.

This experiment indicates that growing a PEGM film on the surface of a silica wafer effectively reduces both reversible and irreversible binding of proteins (Fibrinogen, MW˜360kDa, 60×60×450 Å, pH=pl=6.0) to the wafer surface. For example, a 160 Å thick layer of fibrinogen is adsorbed to the surface of a silica wafer that is not coated with a PEGM film. In addition, an 85 Å thick fibrinogen layer is adsorbed to the surface of a silicon wafer having only the hydrophobic initiator monolayer deposited thereon in accordance with example 4. However, less than a 20 Å thick fibrinogen layer is bound to the surface of a silicon wafer containing a 50 Å thick layer of PEGM film coated on its surface in accordance with Example 5. It appears that up until about 100 Å, increasing the thickness of the PEGM film layer has a significant impact on reducing the reversible adhesion of fibrinogen to the surface. A PEGM layer that is 100 Å thick reduces the thickness of the residual bound protein from a 67 Å thick layer to about a 20 Å thick layer. Table 4 shows how the thickness of a fibrinogen layer that is reversibly and irreversibly adsorbed to the surface of a silica wafer is related to the thickness of a PEGM film that is contained on the surface of the silica wafer.

TABLE 4
Thickness of Protein Layer in Relation to Composition and
Thickness of Materials Applied to the Surface of a Silica Wafer

| | Coating | | |
|---|---|---|---|
| | thickness | Protein | Protein |
| Surface | (Å) | Adsorption (Å) | Desorption (Å) |
| Bare silica | 0 | 178 ± 8 | 67 ± 4 |
| (SiO2) | | | |
| SiO2-Monolayer | 23 | 137 ± 29 | 85 ± 6 |
| SiO2-PEGM | 72 | 16 ± 18 | 11 ± 6 |
| SiO2-PEGM | 94 | 43 ± 19 | 13 ± 11 |
| SiO2-PEGM | 228 | 30 ± 22 | 15 ± 12 |
| SiO2-PEGM | 331 | 1 ± 14 | 3 ± 1 |
| SiO2-PEGM | 381 | 1 ± 14 | 2 ± 15 |

Table 5 summarizes the estimated amount of protein loading that would be needed to obtain a protein layer having the thickness specified. The theoretical loading of fibrinogen is reported to be between 2-16 mg/m² for a side-on and end-on position respectively.

TABLE 5
Estimated Fibrinogen Loading Value Needed to Obtain
a Specific Protein Layer Thickness

| Protein Layer | Loading |
|---|---|
| Thickness Å | mg/m² |
| 160 | 19.2 |
| 50 | 6 |
| 10 | 1.2 |

### EXAMPLE 11

### Cell Adhesion on PEGM-Coated Silicon Wafers

Cell Culture

This example evaluated the degree of adhesion of cells to the surface of three silicon wafers having different surface coatings. Wafer 1 had a bare surface with nothing coated thereon. Wafer 2 was prepared in accordance with Example 4, wherein initiator molecules were self-assembled as a monolayer on the surface of the wafer. Wafer 3 was prepared in accordance with Example 5, wherein a PEGM film was grown on the surface of the wafer. All three of the silicon wafers were sterilized with 80% ethanol and placed in 3 different 50 mL sterilized plastic tubes. 30 mL of LB liquid culture medium and 100 μL of E. Coli (k12 strain) cell stock solution were added to each of these tubes. After incubation for 24 hours at 37° C. by gently shaking, the tubes were statically placed in an incubator at 37° C. for another 24 hours to maximize the adsorption of cells to the wafer surfaces.

Fluorescent Imaging of the Cells

After being incubated, the wafers were removed from the tubes and rinsed three times with distilled water. Each of the wafers was then placed in a small Petri dish. 5 mL of 50 M carboxyfluorescein diacetate solution (in 200 mM sodium phosphate buffer, pH 7.2) was applied so as to cover the wafer in the Petri dish. After incubation at room temperature for 5 min, the wafer was rinsed with distilled water to remove the free dye, and then each wafer was mounted on a glass slide for cell fluorescent observation.

The cell fluorescence on the wafer surface was observed on an Olympus AX 80 fluorescent microscope with a narrow band FITC cube and the images were acquired with a Spot 2 cooled CCD digital camera. The exposure time was standardized against the control, which is bare silicon.

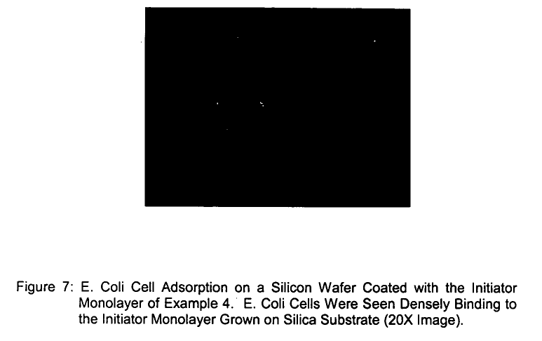

a) For bare silica substrate, the surface was very hydrophilic. As shown in FIG. 6, there appeared to be no E. Coli cells adhered to the surface of the bare silica wafer.

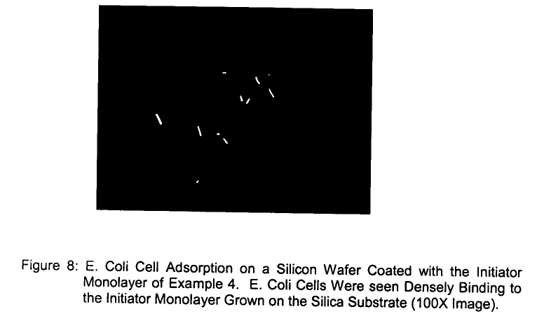

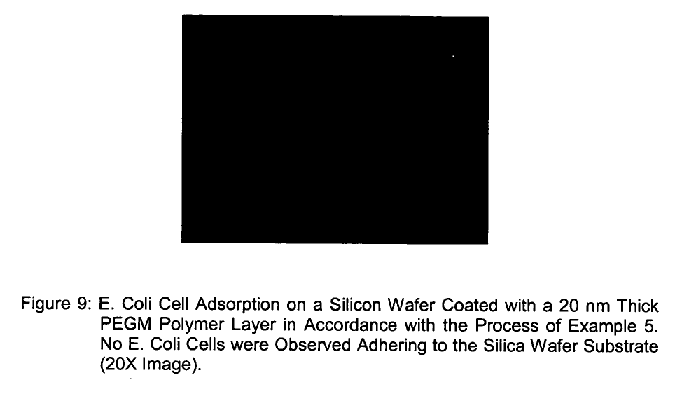

b) As shown in FIGS. 7 and 8, silicon wafers prepared in accordance with Example 4, and then subsequently exposed to a protein buffer solution as disclosed herein above had E. Coli cells densely bound to their surface. This data suggests that hydrophobic polymer plastics do not resist cell binding.

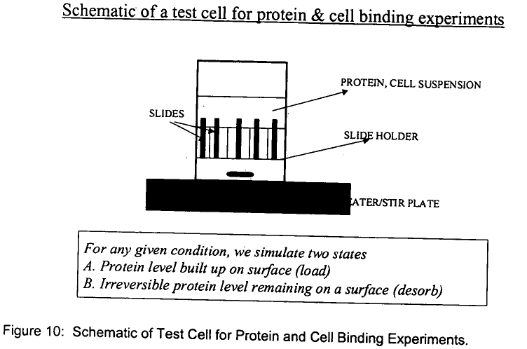

c) The silicon wafers that were coated with PEGM films having various thicknesses (50, 100, 200, 300 and 400 Å) in accordance with Example 5, and then subsequently exposed to a protein buffer solution as disclosed herein above were tested for E. Coli cell binding. The experimental data indicated that no E. Coli cells were adsorbed onto the surface of any of the PEGM-coated-silicon wafer surfaces. More specifically, FIG. 9 shows that no E. Coli cells were adsorbed onto the surface of a substrate coated with a 200 Å thick PEGM film.

1. A process for growing a polyethylene glycol alkyl acrylate (PEGAA) film on a substrate having a moiety accepting surface comprising
(a) contacting at least one initiator molecule with the moiety accepting surface of the substrate to form an initiator coated substrate, said initiator molecule being selected from the group consisting of 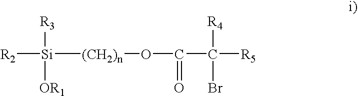
wherein:
n is an integer of 1 to 50;
R₁ and R₄ are each independently a CH₃, C₂H₅, or an alkyl of 3 to 20 carbons;
R₂ and R₃ are each independently a CH₃, C₂H₅, OR₁, or an alkyl of 3 to 20 carbons; and
R₅ is a H, CH₃, C₂H₅, or an alkyl of 3 to 20 carbons, 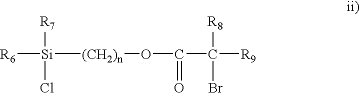
wherein:
n is an integer of 1 to 50;
R₆ and R₇ are each independently Cl, CH₃, C₂H₅, or an alkyl of 3 to 20 carbons;
R₈ is a CH₃, C₂H₅, or an alkyl of 3 to 20 carbons; and
R₉ is a H, CH₃, C₂H₅, or an alkyl of 3 to 20 carbons, and
iii) mixtures thereof; and
(b) further contacting the initiator coated substrate with at least one polyethylene glycol alkyl acrylate monomer in solution, wherein said polyethylene glycol alkyl acrylate monomer has the general formula 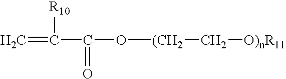
wherein:
n is an integer of 1 to 100; and
R₁₀ and R₁₁ are each independently H, CH3, C₂H₅, or an alkyl of 1 to 20 carbons, further wherein at least one catalyst and optionally at least one ligand are added to the solution containing the polyethylene glycol alkyl acrylate monomer.

2. The process according to claim 1, wherein the moiety accepting surface of the substrate is further contacted in step (a) with at least one spacer molecule, wherein said spacer molecule comprises at least one of
(i) alkyl chains having the following general formulas 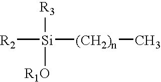
wherein:
n is an integer of 1 to 50;
R₁ is a CH₃, C₂H₅, or an alkyl of 3 to 20 carbons;
R₂ and R₃ are each independently a CH₃, C₂H₅, OR₁, or an alkyl of 3 to 20 carbons; and 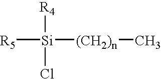
wherein:
n is an integer of 1 to 50;
R₄ and R₅ are each independently Cl, CH₃, C₂H₅, or an alkyl of 3 to 20 carbons;
(ii) phenyl and phenyl derivatives having the following general 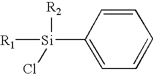
formula
wherein:
R₁ and R₂ are each independently Cl, CH₃, C₂H₅, or an alkyl of 3 to 20 carbons; or
(iii) a mixture of alkyl chains and functional groups having the following general formula 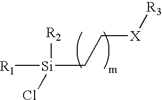
wherein:
m is an integer of 1 to 50;
R₁ and R₂ are each independently Cl, CH₃, C₂H₅, or an alkyl of 3 to 20 carbons;
R3 is a phenyl, OH, NH₂, or an alkyl of 3 to 20 carbons; and
X is an O, COO, or a CONH.

3. The process according to claim 2, wherein the spacer molecule is n-propyl triethoxysilane.

4. The process according to claim 2, wherein the initiator to spacer molecule ratio ranges from about 95:5 mol % to 1:99 mol %.

5. The process according to claim 1 or 2, wherein the initiator molecule is 5′-(triethoxylsilylpentyl) 2-bromo-2-methylpropionate.

6. The process according to claim 1 or 2, wherein the polyethylene glycol alkyl acrylate monomer is polyethylene glycol methacrylate.

7. The process according to claim 1 or 2, wherein the substrate is selected from the group consisting of glass, metal oxide, silicon, fabric, quartz, zirconia and polymeric resins.

8. The process according to claim 1, wherein the polyethylene glycol alkyl acrylate film grown on the surface of the substrate has a thickness ranging from about 0.5 nm to about 5000 nm.

9. The process according to claim 1, wherein the polyethylene glycol alkyl acrylate film grown on the surface of the substrate has a density of polyethylene glycol alkyl acrylate polymer chains ranging from about 0.1% to about 100%.

10. The process according to claim 1 further comprising baking the substrate after said substrate is coated with the at least one initiator molecule, wherein said substrate is baked in an oven at a temperature ranging from 100° C. to 180° C. for a time period ranging from 30 minutes to 10 hours.

11. The process according to claim 1, wherein a polar solvent is added to the solution containing the polyethylene glycol alkyl acrylate monomer.

12. The process according to claim 11, wherein the polar solvent is water.

13. The process according to claim 1 or 2, wherein step (a) is performed in the presence of a solvent.

14. The process according to claim 13, wherein said solvent is selected from the group consisting of water, hydrocarbons, ethers, halogenated hydrocarbons, ketones, methyl ethyl ketones, methyl isobutyl ketones, alcohols, nitriles, esters, carbonates, inorganic solvents, and mixtures thereof.

15. The process according to claim 1 or 2, wherein the ligand is selected from the group consisting of 2,2′-bipyridyl, 1,10-phenanthroline, an alkylamine, a polyamine, and a trialkoxyaluminum.

16. The process according to claim 1 or 2, wherein the catalyst is selected from the group consisting of cuprous chloride, cupric chloride, cuprous bromide, cuprous iodide, cuprous cyanide, cuprous oxide, cuprous acetate, cuprous perchlorate, a tristriphenylphosphine complex of divalent ruthenium (RuCl₂(PPh₃)₃), and tristriphenylphosphine complex of divalent iron (FeCl₂(PPh₃)₃).

17. A biologically resistant device having deposited thereon a polymeric composition comprising
(a) at least one initiator molecule selected from the group consisting of 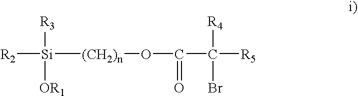
wherein:
n is an integer of 1 to 50;
R₁ and R₄ are each independently a CH₃, C₂H₅, or an alkyl of 3 to 20 carbons;
R₂ and R₃ are each independently a CH₃, C₂H₅, OR₁, or an alkyl of 3 to 20 carbons; and
R₅ is a H, CH₃, C₂H₅, or an alkyl of 3 to 20 carbons, 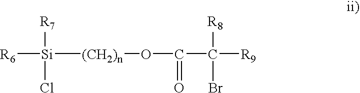
wherein:
n is an integer of 1 to 50;
R₆ and R₇ are each independently Cl, CH₃, C₂H₅, or an alkyl of 3 to 20 carbons;
R₈ is a CH₃, C₂H₅, or an alkyl of 3 to 20 carbons; and
R₉ is a H, CH₃, C₂H₅, or an alkyl of 3 to 20 carbons, and
iii) mixtures thereof; and
(b) at least one polyethylene glycol alkyl acrylate monomer having the general formula 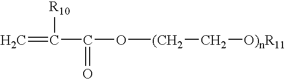
wherein:
n is an integer of 1 to 100; and
R₁₀ and R₁₁ are each independently H, CH3, C₂H₅, or an alkyl of 1 to 20 carbons.

18. The device of claim 17, wherein the initiator molecule of the polymeric composition is 5′-(triethoxylsilylpentyl) 2-bromo-2-methylpropionate.

19. The device according to claim 17, wherein the polyethylene glycol alkyl acrylate monomer of the polymeric composition is polyethylene glycol methacrylate.

20. The device according to claim 17, wherein the polymeric composition optionally further comprises a spacer molecule comprising at least one of
(i) alkyl chains having the following general formulas 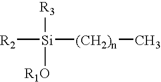
wherein:
n is an integer of 1 to 50;
R₁ is a CH₃, C₂H₅, or an alkyl of 3 to 20 carbons;
R₂ and R₃ are each independently a CH₃, C₂H₅, OR₁, or an alkyl of 3 to 20 carbons; and 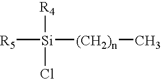
wherein:
n is an integer of 1 to 50;
R₄ and R₅ are each independently Cl, CH₃, C₂H₅, or an alkyl of 3 to 20 carbons;
(ii) phenyl and phenyl derivatives having the following general 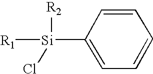
formula
wherein:
R₁ and R₂ are each independently Cl, CH₃, C₂H₅, or an alkyl of 3 to 20 carbons; or
(iii) a mixture of alkyl chains and functional groups having the following general formula 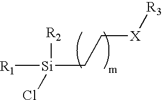
wherein:
m is an integer of 1 to 50;
R₁ and R₂ are each independently Cl, CH₃, C₂H₅, or an alkyl of 3 to 20 carbons;
R3 is a phenyl, OH, NH2, or an alkyl of 3 to 20 carbons; and
X is an O, COO, or a CONH.

21. The device according to claim 20, wherein the spacer molecule of the polymeric composition is n-propyl triethoxysilane.

22. The device according to claim 20, wherein the polymeric composition has an initiator to spacer molecule ratio ranging from about 1:99 to about 99:1.

23. A substrate coated according to the process of claim 1 or 2.

24. The substrate of claim 23, wherein said substrate is selected from the group consisting of glass, metal oxide, silicon, fabrics, porous substrates, quartz, polymeric substrates reinforced with other inorganic materials, zirconia and polymeric resins.

25. The substrate of claim 23, wherein the moiety accepting surface of the substrate has a polyethylene glycol alkyl acrylate chain density ranging from about 0.1% to about 100%.

26. The device of claim 17, comprising a biomedical implant device, biomedical microdevice, membrane-related appliance, prosthetic device, orthopedic implantable device, biosensor, enzyme-linked immunosorbent assay (ELISA) substrate, medical device, patterned cell culture system, tissue engineered material, microfluidic and analytical system material, drug delivery device, high throughput screening system, food packaging material, hygienic product, or electronic material.

27. The device of claim 20, comprising a biomedical implant device, biomedical microdevice, membrane-related appliance, prosthetic device, orthopedic implantable device, biosensor, enzyme-linked immunosorbent assay (ELISA) substrate, medical device, patterned cell culture system, tissue engineered material, microfluidic and analytical system material, drug delivery device, high throughput screening system, food packaging material, hygienic product, or electronic material.

28. A process for growing a polyethylene glycol methacrylate film on a substrate having a hydroxylated surface comprising
(a) contacting 5′-(triethoxylsilylpentyl) 2-bromo-2-methylpropionate mixed optionally with n-propyl triethoxysilane with the hydroxylated surface of the substrate in the presence of toluene; and then
(b) further contacting the surface of the substrate with polyethylene glycol methacrylate in an aqueous solution containing bipyridyl, cuprous chloride and cupric chloride.

29. The process of claim 28, wherein said substrate comprises a biomedical implant device, biomedical microdevice, membrane-related appliance, prosthetic device, orthopedic implantable device, biosensor, enzyme-linked immunosorbent assay (ELISA) substrate, medical device, patterned cell culture system, tissue engineered material, microfluidic and analytical system material, drug delivery device, high throughput screening system, food packaging material, hygienic product, or electronic material.
